(19) United States
(12) Patent Application Publication
(10) Pub. No.: US 2023/0316828 A1
(43) Pub. Date: Oct. 5, 2023

(54) METHOD, NON-TRANSITORY COMPUTER-READABLE STORAGE MEDIUM, AND DEVICE FOR DETERIORATION DIAGNOSIS OF ELECTRONIC UNITS

(71) Applicant: HONDA MOTOR CO., LTD., Tokyo (JP)

(72) Inventors: Hodaka TSUGE, Saitama (JP); Hiroshi ISHIKAWA, Saitama (JP)

(21) Appl. No.: 18/190,352

(22) Filed: Mar. 27, 2023

(30) Foreign Application Priority Data
Mar. 29, 2022 (JP) 2022-053187

(51) Int. Cl. G07C 5/08; B60L 3/12

(52) U.S. Cl. CPC G07C 5/0808; G07C 5/0816; B60L 3/12; B60L 2240/425

(57) ABSTRACT

A deterioration diagnosis method for an electronic control unit (1) including a power semiconductor device (17) and a circuit board (13) supporting the power semiconductor device, comprising the steps of: acquiring a cooling curve based on a detection result of a temperature sensor (43) provided on the power semiconductor device or the circuit board during operation of the power semiconductor device; obtaining a differential curve by time differentiating the cooling curve; approximating the differential curve to an exponential function over a predetermined time range to obtain a corresponding exponent (b); and diagnosing the electronic control unit by comparing the obtained exponent with a predetermined reference value.

### TECHNICAL FIELD

The present invention relates to a method, a non-transitory computer-readable storage medium, and a device for deterioration diagnosis of electronic units, in particular for deterioration diagnosis of electronic units including power semiconductor devices.

### BACKGROUND ART

Methods for predicting the time before failure for electronic control apparatuses such as an electronic control unit including a power semiconductor device and a circuit board electrically connected to the power semiconductor devices are known in the art (See JP2011-253971A, for example).

The power semiconductor device disclosed in JP2011-253971A is fixed to the circuit board via a die attach material. The circuit board is incorporated with a heat-generating thermosensitive device that is provided with a heat-generating layer that generates heat when a voltage is applied thereto and a heat-sensitive layer capable of measuring temperature.

The heat-generating layer of the heat-generating thermosensitive device is heated for an extremely short period of time by applying a short pulse of electric power thereto, and is allowed to cool thereafter. The history of this heating and cooling process is acquired by the heat-sensitive layer as a temperature history (a heat dissipation curve). If a crack is created in the die attach material due to fatigue fracture, and a region of an increased heat resistance is created in the path of heat dissipation from the heat-generating thermosensitive device as a result, alteration occurs to the heat dissipation curve. Thereby, creation of a crack in the die attach material due to fatigue fracture can be detected in an early stage.

In recent years, as a part of efforts to realize a low-carbon or decarbonized society, electric vehicles are attracting attention owing to the reduction in CO₂ emissions and the improvement of energy efficiency which electric vehicles provide. An electric vehicle is provided with a battery, an electric motor, and a power control unit. The power control unit (electronic control unit) contains an inverter that converts the direct current supplied by the battery to alternating current for driving the electric motor. The inverter is equipped with power semiconductors (power semiconductor devices) that function as switching elements.

The method disclosed in JP2011-253971A may be used for detecting deterioration of the power control unit mounted on an electric vehicle. However, according to the method disclosed in JP2011-253971A, it is necessary to control the initial temperature when acquiring the heat dissipation curve. Furthermore, since a heating element is required to be incorporated in the circuit board, the structure of the circuit board becomes undesirably complicated. Therefore, the method disclosed in JP2011-253971A cannot be used for deterioration diagnosis of electronic control units in which ordinary power semiconductor devices are simply mounted on a circuit board.

### SUMMARY OF THE INVENTION

In view of such a problem of the prior art, a primary object of the present invention is to provide a method, a non-transitory computer-readable storage medium and a device for deterioration diagnosis of electronic units which are widely applicable and easy to perform without requiring heating conditions, and initial temperatures for the cooling process to be precisely controlled.

The present invention is also aimed at enhancing the convenience and safety of electric vehicles, and improving energy efficiency.

To achieve such an object, one aspect of the present invention provides a deterioration diagnosis method for an electronic control unit (1) including a power semiconductor device (17) and a circuit board (13) supporting the power semiconductor device thereon, comprising the steps of: acquiring a cooling curve based on a detection result of a temperature sensor (43) provided on the power semiconductor device or the circuit board during operation of the power semiconductor device; obtaining a differential curve by time differentiating the cooling curve; approximating the differential curve to an exponential function over a predetermined time range to obtain a corresponding exponent (b); and diagnosing the electronic control unit by comparing the obtained exponent with a predetermined reference value.

By approximating the differential curve to an exponential function over a predetermined time range, it is possible to obtain an exponent that accurately represents the deterioration of the electronic control unit, so that without regard to the heating condition, the starting temperature of the cooling process, and the cooling temperature. Therefore, the method of the present invention is applicable to a wide range of electronic control units without requiring heating conditions, properties of cooling arrangements, and initial temperatures to be precisely controlled. The method of the present invention is therefore widely applicable and easy to perform.

Preferably, in this deterioration diagnosis method, the electronic control unit is configured to control electric power supplied to a vehicle-mounted electric motor (5), and the step of acquiring the cooling curve is initiated when the vehicle-mounted electric motor is shut down.

Thereby, the influence of the operating condition of the vehicle-mounted electric motor on the detection result of the temperature sensor can be minimized.

Preferably, in this deterioration diagnosis method, an occurrence of deterioration is determined when the obtained exponent is smaller than the reference value.

Thereby, the occurrence or absence of deterioration can be easily determined.

Preferably, in this deterioration diagnosis method, deterioration prediction is performed by comparing a time rate of change of the exponent with a predetermined threshold value.

Thereby, it is possible to determine if the deterioration is accelerating by using the time rate of change of the exponent, so that deterioration prediction can be performed both reliably and easily.

To achieve such an object, another aspect of the present invention provides a non-transitory computer-readable storage medium storing a deterioration diagnosis program for an electronic control unit (1) including a power semiconductor device (17) and a circuit board (13) supporting the power semiconductor device, the program comprising the steps of: acquiring a cooling curve based on a detection result of a temperature sensor (43) provided on the power semiconductor device or the circuit board during operation of the power semiconductor device; obtaining a differential curve by time differentiating the cooling curve; approximating the differential curve to an exponential function over a predetermined time range to obtain a corresponding exponent (b); and diagnosing the electronic control unit by comparing the obtained exponent with a predetermined reference value.

By approximating the differential curve to an exponential function over a predetermined time range, it is possible to obtain an exponent that accurately represents the deterioration of the electronic control unit, so that without regard to the heating condition, the starting temperature of the cooling process, and the properties of cooling arrangements, the program of the present invention is applicable to a wide range of electronic control units without requiring any intensive computation. The program of the present invention is therefore widely applicable and easy to implement.

Preferably, in this non-transitory computer-readable storage medium, the electronic control unit is configured to control electric power supplied to a vehicle-mounted electric motor (5), and the acquisition of the cooling curve is initiated when the vehicle-mounted electric motor is shut down.

Thereby, the influence of the operating condition of the vehicle-mounted electric motor on the detection result of the temperature sensor can be minimized.

Preferably, in this non-transitory computer-readable storage medium, an occurrence of deterioration is determined when the obtained exponent is smaller than the reference value.

Thereby, the occurrence or absence of deterioration can be easily determined.

To achieve such an object, yet another aspect of the present invention provides a deterioration diagnosis device for an electronic control unit (1) including a power semiconductor device (17) and a circuit board (13) supporting the power semiconductor device, the deterioration diagnosis device comprising: a temperature sensor (43) provided on the power semiconductor device or the circuit board; and a processor configured to perform a deterioration diagnosis based on a detection result of the temperature sensor, wherein the processor is configured to acquire a cooling curve based on the detection result of the temperature sensor (43) during operation of the power semiconductor device; obtain a differential curve by time differentiating the cooling curve; approximate the differential curve to an exponential function over a predetermined time range to obtain a corresponding exponent (b); and diagnose the electronic control unit by comparing the obtained exponent to a predetermined reference value.

By approximating the differential curve to an exponential function over the predetermined time range, it is possible to obtain an exponent that accurately represents the deterioration of the electronic control unit, so that without regard to the heating condition, the starting temperature of the cooling process, and the properties of the cooling arrangement, the device of the present invention is applicable to a wide range of electronic control units without requiring any intensive computation. The program of the present invention is therefore widely applicable and easy to implement.

Preferably, in this deterioration diagnosis device, the electronic control unit is a power control unit that controls electric power supplied to a vehicle-mounted electric motor (5), and acquiring the cooling curve is performed when the vehicle-mounted electric motor is shut down.

Thereby, the influence of the operating condition of the vehicle-mounted electric motor on the detection result of the temperature sensor can be minimized.

Preferably, in this deterioration diagnosis device, an occurrence of deterioration is determined when the obtained exponent is smaller than the reference value.

Thereby, the occurrence or absence of deterioration can be easily determined.

The present invention thus provides a method, a non-transitory computer-readable storage medium, and a device for deterioration diagnosis of an electronic device which are widely applicable and easy to perform without requiring heating conditions, and initial temperatures for the cooling process to be precisely controlled.

### BRIEF DESCRIPTION OF THE DRAWING(S)

FIG. 1 is a block diagram of a deterioration diagnosis device according to an embodiment of the present invention, and an electronic control unit to be diagnosed by the deterioration diagnosis device;

FIG. 2 is a sectional view of the electronic control unit that is to be diagnosed;

FIG. 3 is a flowchart of a deterioration diagnosis process according to an embodiment of the present invention;

FIG. 4 is a graph showing cooling curves for three electronic control units that have deteriorated to different degrees;

FIG. 5 is a flowchart showing the process of obtaining the predetermined time range;

FIG. 6 is an example of a cooling curve;

FIG. 7 is a graph showing a predetermined time range obtained from the cooling curve of FIG. 6;

FIG. 8 shows cooling curves that are acquired from the three electronic control units that have deteriorated to different degrees as shown in FIG. 4 with different cooling start temperatures;

FIG. 9 shows three differential curves obtained by time differentiating the cooling curves shown in FIG. 8, and straight lines approximating the differential curves;

FIG. 10 is a graph showing cooling curves obtained by changing the cooling start temperature and coolant temperature in one of the power control units used to obtain the cooling curves shown in FIG. 4;

FIG. 11 is a graph showing differential curves corresponding to the cooling curves shown in FIG. 9;

FIG. 12 is a graph showing the change rate the exponent b obtained in power cycle tests where conditions such as heating time, cooling start temperature, and coolant temperature are fixed (broken lines) and where these conditions are varied randomly (solid lines);

FIG. 13 is a plot diagram showing the relationship between the change rate of the exponent and the coolant temperature obtained by using the data obtained over the predetermined time range (black dots) and by using the data obtained over the entire measurement time (white dots); and

FIG. 14 is a plot diagram showing the relationship between the change rate of the exponent and the cooling start temperature−coolant temperature obtained by using the data obtained over the predetermined time range (black dots) and by using the data obtained over the entire measurement time (white dots).

### DESCRIPTION OF THE PREFERRED EMBODIMENT(S)

A method, a non-transitory computer-readable storage medium, and a device for deterioration diagnosis of electronic devices are described in the following in terms of specific embodiments with reference to the appended drawings.

In the following description, the present invention will be described as being applied to the deterioration diagnosis of an electronic control unit consisting of a power control unit 1.

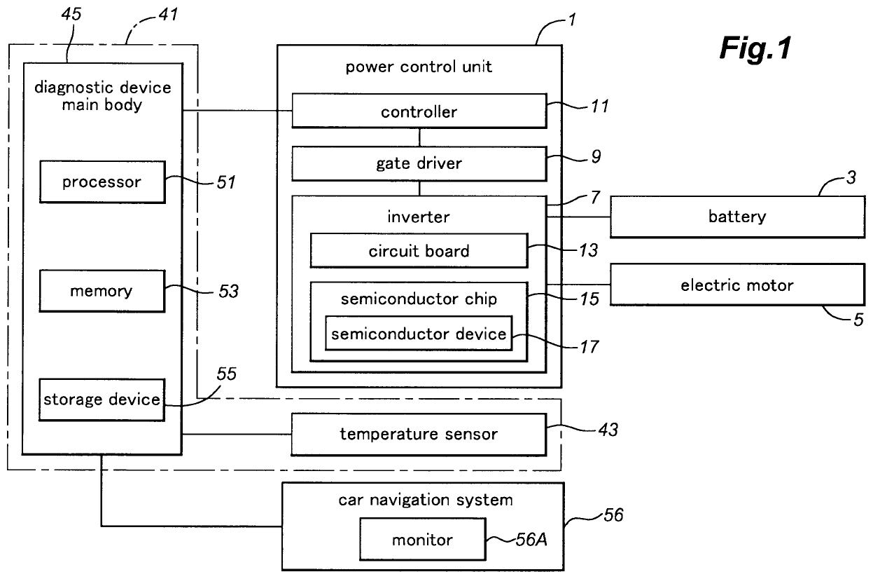

The power control unit 1 is mounted on an electric vehicle to control the electric power supplied to the vehicle-mounted electric motor 5 from a battery 3 mounted on the electric vehicle. As shown in FIG. 1, the power control unit 1 includes an inverter 7 that converts direct current supplied from the battery 3 into alternating current for driving the electric motor 5, a gate driver 9 that directly controls the operation of the inverter 7, and a controller 11 for setting the operating conditions of the gate driver 9 according to control inputs such as an accelerator depression. In this embodiment, the present invention is applied to the deterioration diagnosis of the inverter 7.

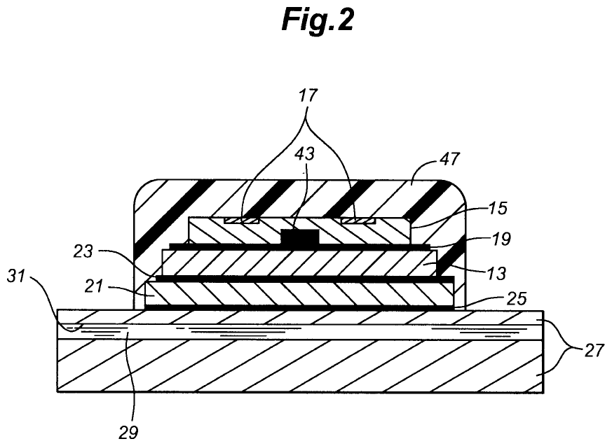

FIG. 2 is a schematic sectional view showing a part of the inverter 7 which includes a circuit board 13 and a semiconductor chip 15 (power semiconductor device) mounted thereon.

The circuit board 13 is made of an insulating material having a high thermal conductivity and a capability to withstand high voltage. The circuit board 13 may include a ceramic or aluminum nitride substrate and a thick copper layer deposited thereon, the copper layer serving as a heat conductor and/or providing a circuit pattern. A plurality of electrodes (not shown in the drawings) are provided on one side (the upper surface) of the circuit board 13 for electronic components mounted on the circuit board 12 and for external connections. The inverter 7 may be used in various orientations, but for the convenience of description, it is assumed that the semiconductor chip 15 is positioned on top of (above) the circuit board 13 as illustrated in FIG. 2.

The semiconductor chip 15 is incorporated with a plurality of semiconductor devices 17 which are designed to control the electric power supplied to the electric motor 5, and are thus power devices (power semiconductor devices). The semiconductor devices 17 may also be bipolar transistors or power MOSFETs (metal-oxide semiconductor filed-effect transistors).

The semiconductor chip 15 is bonded to the upper surface of the circuit board 13 with a bonding material. Thereby, the semiconductor devices 17 provided on the semiconductor chip 15 are respectively supported by the circuit board 13 made of an insulator.

The bonding material may consist of solder, sintered metal material, etc. In this embodiment, the semiconductor chip 15 and the circuit board 13 are joined by solder, and a solder layer 19 is therefore provided between the semiconductor chip 15 and the circuit board 13.

The semiconductor devices 17 are connected to electrodes provided on the circuit board 13 via bonding wires (not shown in the drawings). The electrodes provided on the circuit board 13 are connected to the wiring pattern provided on the circuit board 13 or to electric wiring separate from the circuit board 13. A voltage is applied to the semiconductor devices 17 via the wiring pattern or the electric wiring, and the semiconductor devices 17 function as switching elements for configuring the inverter 7.

The other side (the lower surface) of the circuit board 13 is bonded to a heat sink 21 with a bonding material. The bonding material may composed of solder, metal sintered material, or the like. In this embodiment, the circuit board 13 and the heat sink 21 are joined by soldering, and a solder layer 23 is therefore provided between the circuit board 13 and the heat sink 21.

The heat sink 21 is placed on a cooling device 27 via a heat transfer layer 25 made of thermal interface material. The thermal interface material is a material that fills small gaps and irregularities between the heat sink 21 and the cooling device 27 to efficiently conduct heat from the heat sink 21 to the cooling device 27. The heat transfer layer 25 may be made of, for example, a pad, paste, grease, or the like having high thermal conductivity.

The cooling device 27 may be made of metal, and provided internally with a channel 31 for circulating a coolant 29 therein. The coolant 29 may be, for example, cooling water or the like. However, the present invention is not limited to this example; the cooling device 27 may be formed as fins formed in the heat sink 21, and may also include an electric fan for moving air along the fins.

It is known that the solder layer 19 between the semiconductor chip 15 and the circuit board 13 and/or the solder layer 23 between the circuit board 13 and the heat sink 21 may demonstrate cracks which adversely affect the thermal conductivity of the solder layer 19, 23 due to various factors such as thermal cycles. The present invention may be applied to diagnose such deterioration of an electronic control unit. However, this is only an example, and the present invention is applicable to diagnosing deterioration of other parts of electronic control units, and deteriorations of other natures that may occur in electronic control units.

Next, a deterioration diagnosis device 41 for an electronic control unit configured to implement the deterioration diagnosis method for an electronic control unit according to an embodiment of the present invention will be described in the following. The deterioration diagnosis device 41 is designed to diagnose the deterioration of the power control unit 1, in particular the solder layers 19 and 23 of the inverter 7, by executing the deterioration diagnosis method for an electronic control unit. As shown in FIG. 1, the deterioration diagnosis device 41 includes a temperature sensor 43 and a diagnostic device main body 45 that performs the deterioration diagnosis based on the detection result of the temperature sensor 43.

The temperature sensor 43 in this embodiment consists of a temperature-measuring diode. However, the temperature sensor 43 is not limited to this embodiment, and may be composed of, for example, a resistance thermometer whose resistance value changes with temperature, a thermistor, or the like. Alternatively, a calibration curve relating the resistance value of the semiconductor chip 15 to the temperature may be prepared in advance to detect the temperature from the resistance value of the semiconductor chip 15.

As shown in FIG. 2, the temperature sensor 43 is provided on the lower surface of the semiconductor chip 15. Therefore, the temperature detected by the temperature sensor 43 is approximately equal to the temperature of the semiconductor chip 15. However, the positioning of the temperature sensor 43 is not limited to this example, and the temperature sensor 43 may also be provided on either the upper surface or the lower surface of the circuit board 13 or the upper surface of the semiconductor chip 15. Alternatively, the temperature sensor 43 may be provided inside the circuit board 13. In this embodiment, the temperature sensor 43 is formed on the lower surface of the semiconductor chip 15 and fixed to the upper surface of the circuit board 13 via the solder layer 19 existing between the semiconductor chip 15 and the circuit board 13.

In this embodiment, the semiconductor chip 15, the temperature sensor 43, the circuit board 13, and the heat sink 21 are integrally sealed with molded resin so as to form a semiconductor package 47.

As shown in FIG. 1, the diagnostic device main body 45 includes a processor 51 (central processing unit, CPU), memory 53 such as RAM (random access memory) and ROM (read only memory), and a storage device 55 such as an HDD (hard disk drive) and SSD (solid state drive). The diagnostic device main body 45 may be connected to, for example, a car navigation system 56 having a monitor 56A inside the vehicle.

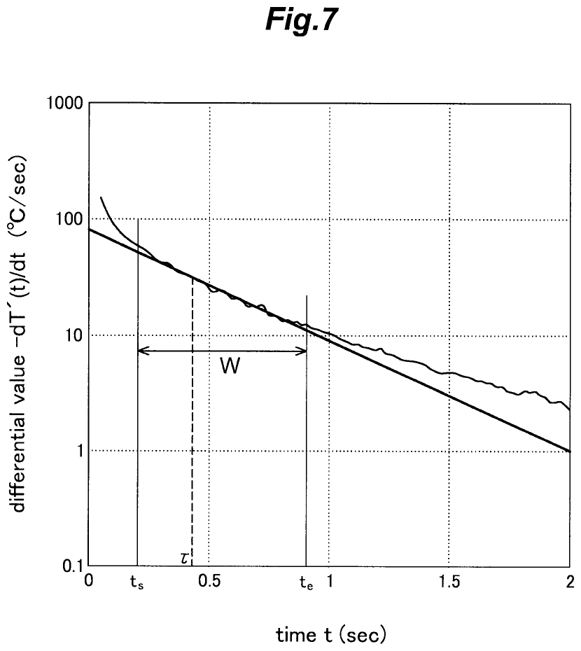

The diagnostic device main body 45 (more specifically, the storage device 55 of the diagnostic device main body 45) stores a predetermined range W which is defined as a time interval ranging between a start time tₛ or a time point following the start of measurement tₛ by a prescribed time period (tₛ) and an end time tₑ or a time point following the start time by another prescribed time period W (see FIG. 7). The predetermined range W is stored in the storage device 55. When this deterioration diagnostic device is configured to be mounted on a vehicle as an onboard device, the predetermined range W may be stored in the storage device 55 before the vehicle is rolled out from the factory.

The diagnostic device main body 45 is connected to the controller 11 of the power control unit 1. The controller 11 of the power control unit 1 controls the operation of the electric motor 5 by controlling the inverter 7 via the gate driver 9. The processor 51 of the diagnostic device main body 45 acquires a signal indicating that the electric motor 5 has ceased to operate from the operating state from the controller 11.

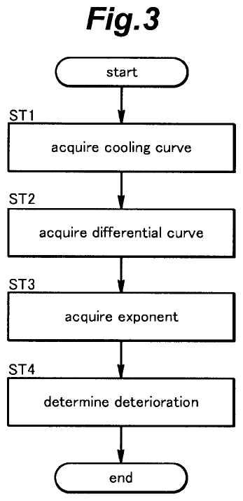

When the processor 51 has acquired a signal from the controller 11 indicating that the electric motor 5 has ceased operation from the operating state, the processor 51 executes a deterioration diagnosis program for the power control unit 1. By executing the deterioration diagnosis program, the processor 51 performs the deterioration diagnosis process outlined in the flowchart shown in FIG. 3, and implements the deterioration diagnosis method for the power control unit 1. Thereby, the processor 51 diagnoses the presence or absence of deterioration of the power control unit 1 (specifically, the presence or absence of deterioration of the solder layers 19 and 23 provided in the inverter 7 of the power control unit 1). Details of the deterioration diagnosis process will be described in the following with reference to the flowchart of FIG. 3.

In the first step of the deterioration diagnosis process, or in step ST1, the processor 51 acquires the detection result of the temperature sensor 43 at a regular time interval Δt from the time point (t=0) at which the electric motor 5 is deactivated until a predetermined time (hereinafter referred to as measurement time tₘₐₓ) has elapsed from the time point at which the electric motor 5 is deactivated.

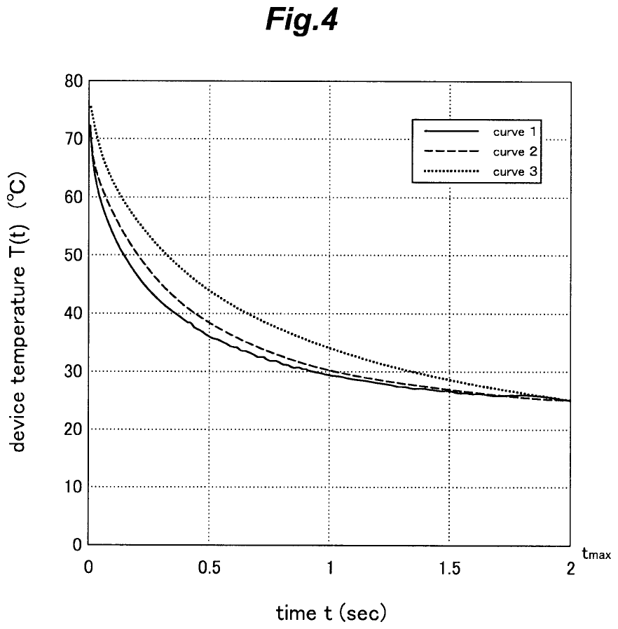

Thus, the data acquired by the processor 51 represents the time history of the temperature T acquired by the temperature sensor 43 from time t=0 to tₘₐₓ, where time t=0 corresponds to the time point at which the electric motor 5 is deactivated (see FIG. 4, for example). In this embodiment, the temperature sensor 43 acquires the temperature T of the semiconductor device 17 (device), so that the data acquired by the processor 51 is the temperature T of the semiconductor device 17 from time t=0 to tₘₐₓ. In this embodiment, since the temperature sensor 43 acquires the temperature T of the semiconductor device 17, the data acquired by the processor 51 is a change in the temperature T (cooling curve) of the semiconductor device 17 over the time range of t=0 to tₘₐₓ. The measurement time tₘₐₓ may be on the order of several seconds, and the time interval Δt may be on the order of about 10 μs. Upon elapsing of the measurement time tₘₐₓ, the processor 51 stops acquiring the detection result, and executes step ST2.

In step ST2, the processor 51 obtains a differential curve (−dT(t)/dt) by time differentiating the cooling curve, and inverting the sign. The differential curve corresponds to a curve that indicates the magnitude of the slope of the cooling curve. The time differentiation of the cooling curve may be performed by using a per se known numerical differentiation process which may be based on forward difference, central difference, etc. Once the differential curve is obtained, the processor 51 executes step ST3.

In step ST3, the processor 51 obtains the predetermined range W from the storage device 55, approximates the differential curve to an exponential function over the predetermined range W, and obtains the corresponding exponent b.

The exponent b here is a coefficient of time t when the temperature T(t) is represented by the following formula (1), and is the reciprocal of the time constant B (which may also be referred to as relaxation time) (b=1/B).

$$T ( t ) = - A exp ( - \frac{t}{B} ) + C = - A exp ( - bt ) + C \qquad ( 1 )$$

where A and C are predetermined constants.

In this embodiment, the processor 51 first acquires a logarithmic conversion curve Y obtained by logarithmically transforming the differential curve (−dT(t)/dt) with a base e (or logₑ(−dT/dt)), where e denotes the base of natural logarithm.

Next, the processor 51 performs a regression analysis on the logarithmic conversion curve Y. More specifically, the processor 51 assumes that the logarithmic conversion curve Y can be represented by a straight line, or by an approximate expression of Y=−bt+b0 in the predetermined range W, and obtains the exponent b by a per se known method. After obtaining the exponent b, the processor 51 executes step ST4.

In step ST4, the processor 51 determines the progress of deterioration based on the exponent b. In this embodiment, the processor 51 determines that the power control unit 1 has not critically deteriorated when the exponent b is equal to or greater than a predetermined abnormality determination reference value b0, and when the exponent b is smaller than the abnormality determination reference value b0, it is determined that the power control unit has critically deteriorated. When the deterioration determination is completed, the processor 51 ends the deterioration diagnosis process.

When the processor 51 has determined that the power control unit 1 has deteriorated, the processor 51 may cause the monitor 56A of the car navigation system 56 to display that the power control unit 1 has critically deteriorated. For example, if the diagnostic device main body 45 is configured to be connected to a vehicle owner's mobile terminal (smartphone, etc.) via a network, the diagnostic device main body 45 may detect the deterioration of the power control unit 1, and notify this to the vehicle owner via the mobile terminal.

Next, a method for obtaining the predetermined range W to be stored in the storage device 55 (hereinafter referred to as predetermined range obtaining method) will be described in the following. The predetermined range acquisition method is performed by executing a predetermined range acquisition process with a test device (deterioration diagnosis device 41) that tests a reference unit or a power control unit 1 having the same specifications (structure) as the power control unit 1 actually mounted on the vehicle.

The test device may execute the predetermined range acquisition process during the design stage of the power control unit 1. Also, the test device may execute the predetermined range acquisition process for a reference unit that has completed an initial stress process (that causes the product to undergo 10,000 power cycle tests).

The test device is provided with a temperature sensor that measures the temperature of a semiconductor chip provided in the reference unit, a processor that analyzes the detection results of the temperature sensor, and a display unit such as a monitor that displays the results analyzed by the processor. The test device may have the same configuration as the deterioration diagnostic device (the diagnostic device main body 45 and the temperature sensor 43 that measures the temperature of the power control unit 1). Further, when the predetermined range acquisition process is carried out, the power control unit 1 is supplied with a coolant 29 at a constant temperature, and the temperature of the coolant (hereinafter referred to as coolant temperature) is set to a predetermined value (hereinafter referred to as a test coolant temperature).

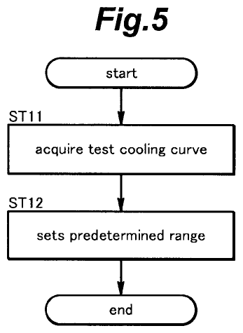

Details of the predetermined range acquisition process will be described in the following with reference to FIG. 5.

In the first step or step ST11 of the predetermined range acquisition method, the test device heats the semiconductor chip included in the reference unit for a certain time period, and upon ceasing of the heating, the temperature of the semiconductor chip (chip temperature T′(t)) is acquired until a predetermined time (hereinafter referred to as test measurement time tₘₐₓ′) has elapsed. The test measurement time tₘₐₓ′ may be either the same or different from the measurement time tₘₐₓ.

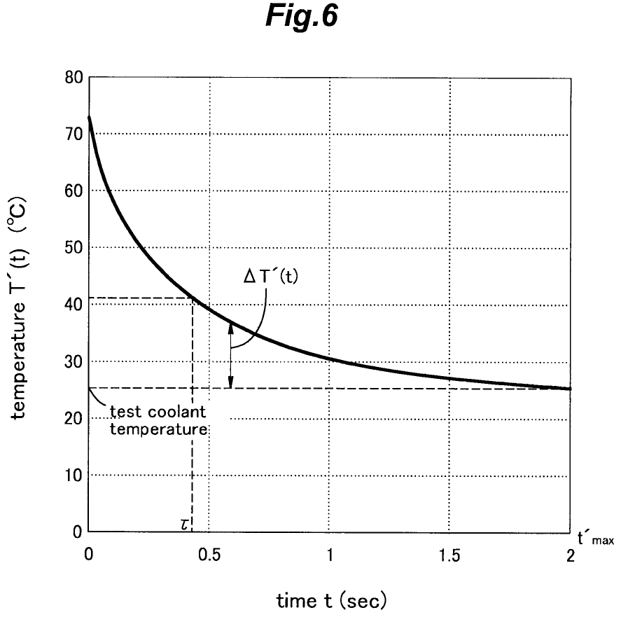

At this time, the data acquired by the test device corresponds to the time history of the temperature T′(t) from time t=0 or the time point at which the heating is stopped to t=tₘₐₓ′(test measurement time) (a test cooling curve), as shown in FIG. 6. When the test measurement time tₘₐₓ′ has elapsed, the test device stops temperature acquisition and executes step ST12.

In step ST12, the test device calculates a differential temperature ΔT′(t) by calculating a value obtained by subtracting the test coolant temperature from the temperature T′(t). The test device then calculates the value of 1/e (e is the base of natural logarithm) times the differential temperature ΔT′(t) at time t=0.

Thereafter, the test device determines the time period required for the differential temperature ΔT′(t) to become 1/e times the value of the differential temperature at t=0 (in other words, the time required for the temperature T′(t) becomes lower than (cooling start temperature−coolant temperature)/e+coolant temperature) as a provisional time constant τ (see FIG. 6). After that, the test device sets a predetermined range W as a time period having a predetermined width including the provisional time constant τ.

In this embodiment, the test device plots the differential value (−dT′(t)/dt) of the temperature T′(t) on a semilogarithmic graph (see FIG. 7). After that, the test device selects a predetermined range W that includes the provisional time constant τ and demonstrates a contribution ratio (R2) of about 0.99 over a widest possible range. The contribution ratio R2 referred to here is a degree of deviation of the logarithm of the differential value of the temperature T′(t) from a straight line when it is assumed that the logarithm (log (−dT′(t)/dt)) of the differential value of the temperature T′(t) can be approximated by the straight line over the predetermined range W. The contribution ratio R2 may also be called as an R-square value or a coefficient of determination. Optionally, the test device may be configured such that the predetermined range W may be altered by an input by an operator. In doing so, it should be noted that the narrower the predetermined range W is, the smaller the value of the contribution ratio R2 becomes, and the wider the predetermined range W is, the larger the value of the contribution ratio R2 becomes.

When the setting of the predetermined range W is completed, the test device displays the predetermined range W on the display unit, and completes the predetermined range acquisition process.

A worker who performs the test work using this test device, a worker who assembles and maintains automobiles, etc. may perform input work as appropriate, and store the predetermined range W in the storage device 55.

Next, the features and advantages of the deterioration diagnosis method and the deterioration diagnosis device 41 configured in this manner will be described in the following with reference to the appended drawings.

FIG. 4 shows an example of a cooling curve plotted with time t on the horizontal axis and temperature T on the vertical axis.

The more active the heat transfer from the semiconductor chip 15 to the cooling device 27 is, the faster the temperature of the semiconductor chip 15 drops. If a crack is generated in the solder layer 19 or 23 (fissure or crack), the heat resistance in transferring the heat from the semiconductor chip 15 to the cooling device 27 increases so that the cooling rate of the semiconductor chip 15 decreases. For example, FIG. 4 shows that the cooling rates of the semiconductor chip 15 represented by curves 2 and 3 are less than that represented by curve 1 in FIG. 4. By evaluating the cooling rate in this way, it is possible to determine if any of the solder layers 19 and 23 has deteriorated or not.

However, since the cooling start temperature (the temperature of the semiconductor chip 15 when the cooling is started) and the coolant temperature may vary depending on the driving conditions and driving environment of the vehicle, a general comparison cannot be made.

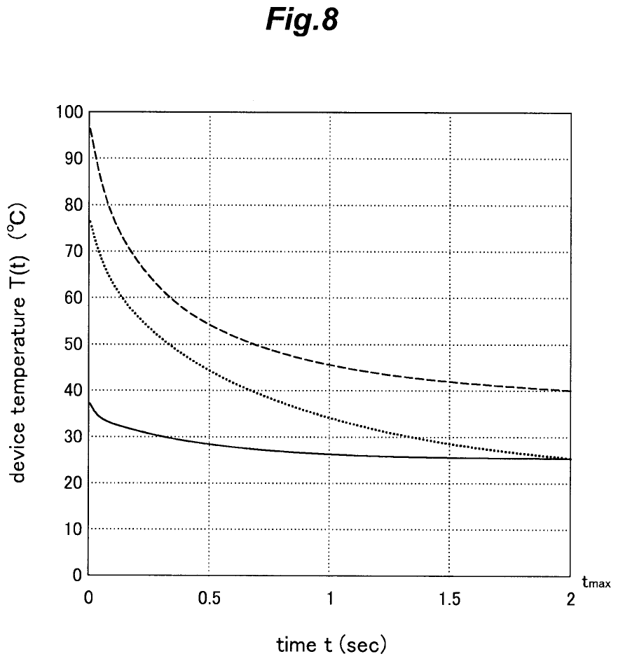

FIG. 8 shows cooling curves obtained by changing the cooling start temperature and coolant temperature in the power control unit 1 corresponding to curves 1 to 3 of FIG. 4, respectively. It is difficult to judge the cooling rate, or the progress of the deterioration of the power control unit 1 from this graph.

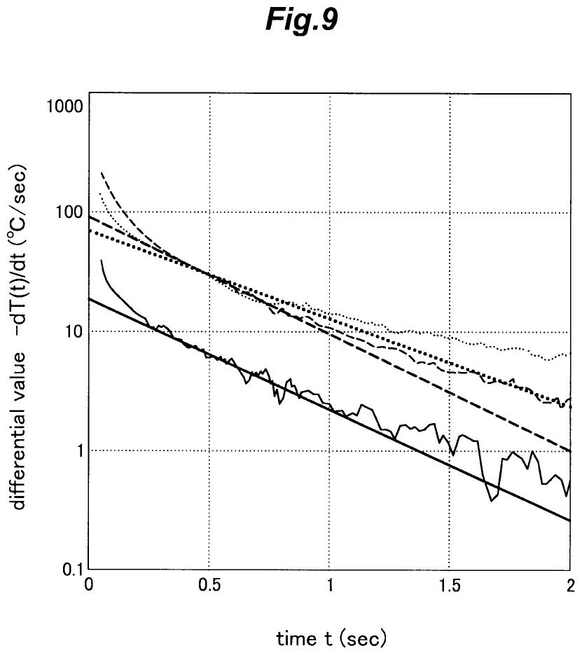

To overcome this problem, the present inventors have discovered that when the cooling curve is time-differentiated and plotted on a semi-logarithmic graph with the y-axis (logarithmic scale) representing the time-differentiated temperature and the x-axis (linear scale) representing time (see FIG. 9), the slope of the time-differentiated temperature is substantially constant over a certain range (predetermined range W) without regard to the cooling start temperature or the coolant temperature. In other words, the time-differentiated value of the cooling curve can be approximated by an exponential function within a predetermined range W so that when plotted on a semilogarithmic graph, the slope is constant even if the cooling start temperature or coolant temperature varies. For example, according to the graph shown in FIG. 9, since the progress of deterioration can be determined from the slope of the line, the evaluation of the progress of deterioration can be simplified.

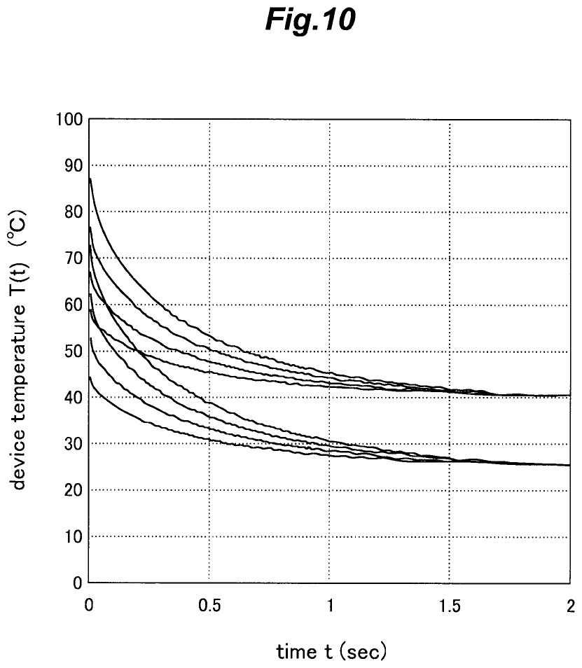

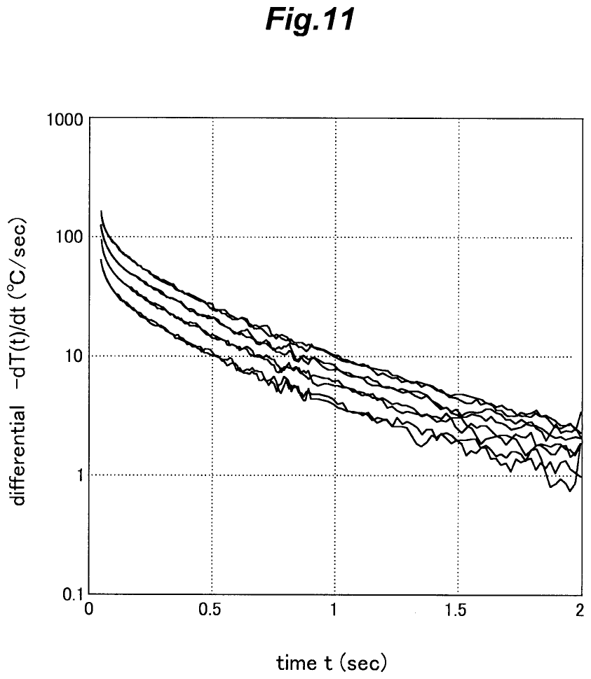

FIG. 10 shows cooling curves obtained by changing the cooling start temperature and coolant temperature in one of the power control units 1 used to obtain curves 1 to 3 shown in FIGS. 4, 8, and 9. FIG. 11 shows differential curves obtained by differentiating the cooling curves shown in FIG. 10.

Table 1 below shows the slopes (exponents b) that are obtained from the curves shown in FIG. 11.

TABLE 1

| cooling start | coolant temp. | exponent b |
|---|---|---|
| temp. (° C.) | (° C.) | (1/sec) |
| 44 | 25 | 2.12 |
| 52 | 25 | 2.13 |
| 62 | 25 | 2.15 |
| 72 | 25 | 2.12 |
| 59 | 40 | 2.14 |
| 67 | 40 | 2.13 |
| 76 | 40 | 2.15 |
| 87 | 40 | 2.14 |

From Table 1, it can be concluded that the exponent b is substantially the same without regard to the variations in the cooling start temperature and/or the coolant temperature, and if the degree of deterioration is the same, the exponent b will be the same.

The cooling curve of the semiconductor device 17 mounted on the power control unit 1 is theoretically expressed by the following formula (2).

$$T ( t ) = C + {\sum }_{i = 1}^{N} ( - {A}_{i} exp ( - {b}_{i} t ) ) \qquad ( 2 )$$

In formula (2), C, Ai and bi (i=1 to N) are predetermined constants independent of time t, and N is a predetermined positive integer of 1 or greater. Since Formula (2) is not a single exponential function, and does not produce a single exponential function even when differentiated, it is inconsistent with the fact that the slope is constant when plotted on a semilogarithmic graph (see FIG. 6).

Equation (2) can also be expressed as Equation (3).

T(t)=C−A₁exp(−b₁t)−A₂exp(−b₂t)−A₃exp(−b₃t) (3)

The inventors of the present application have discovered that in Formula (2) (or Formula (3)), there is a range (predetermined range W) in which a certain term, for example, the n term (−Aₙexp (−bnt)) is so dominant that the other terms change little with time (or can be approximated by constants) or deviate from this assumption only at the beginning of the cooling curve. In other words, the inventors of the present application have discovered that, over the predetermined range W, Formula (3) can be approximated by Formula (4) given in the following.

$$T ( t ) = - A exp ( - \frac{t}{B} ) + C = - A exp ( - bt ) + C \qquad ( 4 )$$

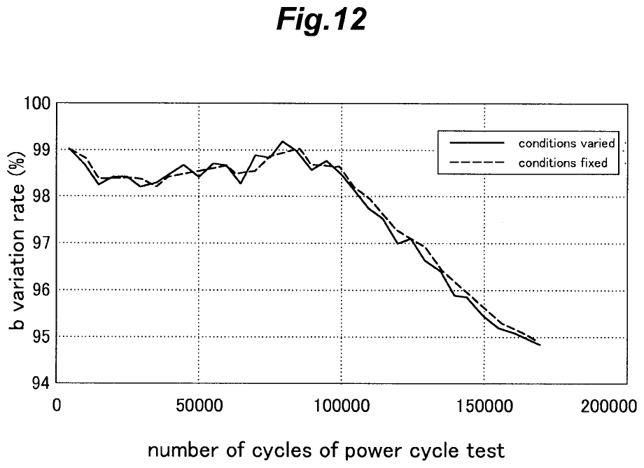

FIG. 12 shows the exponent b obtained in the power cycle tests when the heating time, cooling start temperature, and coolant temperature are fixed (broken lines) and when these values are changed randomly (solid lines) based on such consideration. As can be seen from FIG. 12, according to the deterioration diagnosis method of the present embodiment, the deterioration state of the power control unit 1 can be detected from the value of the exponent b even if the heating time, cooling start temperature, and coolant temperature change.

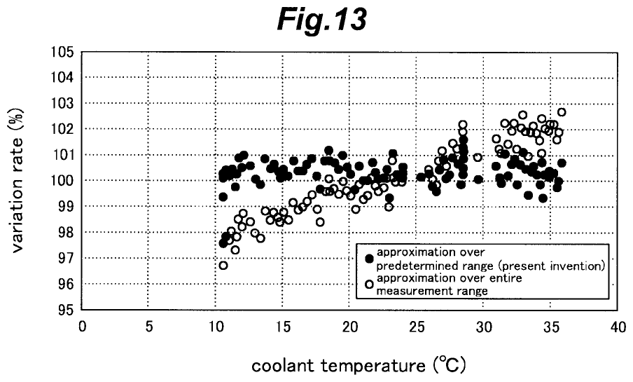

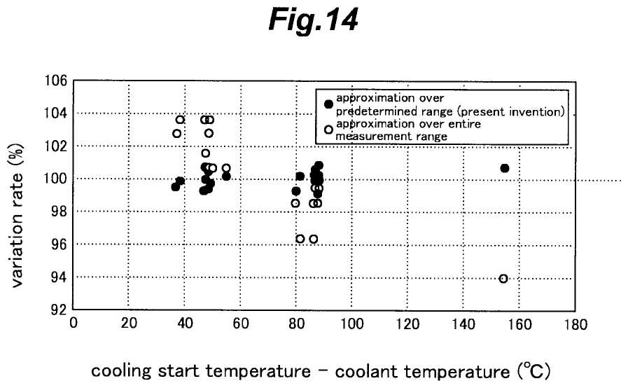

In addition, the relationship between the coolant temperature and the variation rate of the exponent b is shown by black dots in FIG. 13, and the relationship between (cooling start temperature−coolant temperature) and the variation rate of the exponent b is shown by black dots in FIG. 14. For comparison, the value of the exponent b when the entire cooling curve is assumed to be an exponential function without using this method is also indicated by white dots in FIGS. 13 and 14.

From FIG. 13, it can be seen that the deterioration diagnosis method of the present embodiment can acquire the exponent b representing the state of deterioration without being affected by the cooling start temperature and coolant temperature. From the black dots and white dots shown in FIGS. 13 and 14, it can be seen that when the state of deterioration is computed from the entire cooling curve instead of using the deterioration diagnosis method of the present invention, the value of the exponent b is greatly affected by the cooling start temperature and the coolant temperature. Therefore, it can be seen that the method of calculating the state of deterioration from the entire cooling curve without using the deterioration diagnosis method according to the present invention is unable to accurately diagnose the state of deterioration.

As described above, the present invention provides a deterioration diagnosis method for an electronic unit which is widely applicable and easy to implement regardless of the heating condition, cooling start temperature, coolant temperature, and the like. As a result, the convenience and safety of electric vehicles are enhanced, so the present invention can be expected to contribute to the improvement of energy efficiency.

In step ST4, the processor 51 determines that the electronic control unit 1 has deteriorated when the exponent b is smaller than an abnormality determination reference value b0. In this way, the state of deterioration can be determined by comparing the exponent b with the abnormality determination reference value b0, so that the occurrence of an unacceptable degree of deterioration can be both easily and accurately detected.

When the processor 51 acquires a signal indicating that the electric motor 5 has transitioned from the activated state to the deactivated state, the processor 51 executes a deterioration diagnosis process, and starts acquiring a cooling curve. Owing to this arrangement, the influence of the vehicle-mounted electric motor 5 such as electromagnetic noises, etc. on the detection result of the temperature sensor 43 can be reduced as compared to the case where the acquisition of the cooling curve is started while the electric motor 5 is still being operated.

As a modified example, it may be arranged such that the processor 51 stores the exponent b in the storage device 55 together with the time at which the deterioration diagnosis process was performed in step ST4, and evaluates the change of the exponent b accumulated in the storage device 55 over time. Thereby, a favorable deterioration prediction is enabled. It is also conceivable to perform deterioration prediction by evaluating the change of the exponent b over a unit time interval or a time change range of exponent b.

In order to acquire the time rate of change of the exponent b, for example, in step ST4, the processor 51 may first retrieve the time sₐ at which the previous deterioration diagnosis process was performed from the storage device 55 and the exponent b(sₐ) obtained in the previous deterioration diagnosis process. Then, the processor 51 calculates the absolute value of the difference (Δb=|b(s_{b})−b(sₐ)|) between this exponent b(sₐ) and the exponent b(s_{b}) that is newly acquired in step ST3. Further, the processor 51 obtains the elapsed time Δs (=s_{b}−s_{b}) from the time sₐ at which the previous deterioration diagnosis process was performed to the time s_{b} at which step ST1 was executed, and the absolute value Δb of the difference between the exponents b is divided by the elapsed time Δs to obtain the value (Δb/Δs) which may be considered as the time rate of change of the exponent b. The processor 51 may determine that the critically deteriorated state is approaching when the time rate of change of the exponent b is equal to or greater than a predetermined threshold.

This completes the description of the specific embodiments, but the present invention can be widely modified without being limited to the above embodiments.

According to the above embodiment, in step ST4 of the deterioration diagnosis process, the processor 51 logarithmically transforms the differential curve with e as the base, performs regression analysis, and acquires the exponent b, but the present invention is not limited to this embodiment. In step ST4 of the deterioration diagnosis process, the processor 51 may also logarithmically transform the differential curve with 10 or any other number as the base, perform regression analysis, and acquire the exponent b.

In the above embodiment, the processor 51 determines that the power control unit 1 has deteriorated when the exponent b becomes smaller than the abnormality determination reference value b0 in step ST4, but the present invention is not limited to this embodiment. In step ST3, the processor 51 may acquire the reciprocal of b (1/b, which may also be referred to as time constant B), and when the time constant B is greater than an abnormality determination reference value B0, the electronic control unit (power control unit 1) may be determined to have critically deteriorated.

In the above embodiment, in step ST3, the processor 51 may assume that the differential curve is represented by the sum of a plurality of exponential functions, and fit a differential curve based on a per se known technique to obtain an exponent b corresponding to each exponential function. In this case, in step ST4, the processor 51 may determine the occurrence of critical deterioration based on the difference between the smallest exponent b (or the largest time constant B) and a corresponding abnormality determination reference value b0 (or an abnormality determination reference time constant B0). Specifically, the processor 51 may determine that the power control unit 1 has critically deteriorated when the smallest exponent b is smaller than an abnormality determination reference value b0 (or when the largest time constant B is larger an abnormality determination reference time constant B0). Since the smaller the exponent b is, the less active is the heat dissipation, by choosing the smallest exponent, the progress of deterioration in a part where the heat dissipation is obstructed by a crack can be effectively detected.

Further, the processor 51 may select the predetermined range W so as to include (center around, for instance) the time point at which the initial value of the differential curve becomes 1/e (e is the base of natural logarithm) each time the deterioration diagnosis process is performed based on the differential curve acquired in ST2.

In the above embodiment, instead of the processor 51, a per se known analog circuit such as a differentiation circuit and/or a logarithmic conversion circuit may be used.

Moreover, not all of the constituent elements shown in the above embodiments are essential to the broad concept of the present invention, and they can be appropriately selected, omitted and substituted without departing from the gist of the present invention. The contents of any cited references in this disclosure will be incorporated in the present application by reference.

1. A deterioration diagnosis method for an electronic control unit including a power semiconductor device and a circuit board supporting the power semiconductor device thereon, comprising the steps of:
acquiring a cooling curve based on a detection result of a temperature sensor provided on the power semiconductor device or the circuit board during operation of the power semiconductor device;
obtaining a differential curve by time differentiating the cooling curve;
approximating the differential curve to an exponential function over a predetermined time range to obtain a corresponding exponent; and
diagnosing the electronic control unit by comparing the obtained exponent with a predetermined reference value.

2. The deterioration diagnosis method according to claim 1, wherein the electronic control unit is configured to control electric power supplied to a vehicle-mounted electric motor, and the step of acquiring the cooling curve is initiated when the vehicle-mounted electric motor is shut down.

3. The deterioration diagnosis method according to claim 1, wherein an occurrence of deterioration is determined when the obtained exponent is smaller than the reference value.

4. The deterioration diagnosis method according to claim 1, wherein deterioration prediction is performed by comparing a time rate of change of the exponent with a predetermined threshold value.

5. A non-transitory computer-readable storage medium storing a deterioration diagnosis program for an electronic control unit including a power semiconductor device and a circuit board supporting the power semiconductor device, the program comprising the steps of:
acquiring a cooling curve based on a detection result of a temperature sensor provided on the power semiconductor device or the circuit board during operation of the power semiconductor device;
obtaining a differential curve by time differentiating the cooling curve;
approximating the differential curve to an exponential function over a predetermined time range to obtain a corresponding exponent; and
diagnosing the electronic control unit by comparing the obtained exponent with a predetermined reference value.

6. The non-transitory computer-readable storage medium according to claim 5, wherein the electronic control unit is configured to control electric power supplied to a vehicle-mounted electric motor, and the acquisition of the cooling curve is initiated when the vehicle-mounted electric motor is shut down.

7. The non-transitory computer-readable storage medium according to claim 5, wherein an occurrence of deterioration is determined when the obtained exponent is smaller than the reference value.

8. A deterioration diagnosis device for an electronic control unit including a power semiconductor device and a circuit board supporting the power semiconductor device, the deterioration diagnosis device comprising:
a temperature sensor provided on the power semiconductor device or the circuit board; and a processor configured to perform a deterioration diagnosis based on a detection result of the temperature sensor,
wherein the processor is configured to
acquire a cooling curve based on the detection result of the temperature sensor during operation of the power semiconductor device;
obtain a differential curve by time differentiating the cooling curve;
approximate the differential curve to an exponential function over a predetermined time range to obtain a corresponding exponent; and
diagnose the electronic control unit by comparing the obtained exponent to a predetermined reference value.

9. The deterioration diagnosis device according to claim 8, wherein the electronic control unit is a power control unit that controls electric power supplied to a vehicle-mounted electric motor, and acquiring the cooling curve is performed when the vehicle-mounted electric motor is shut down.

10. The deterioration diagnosis device according to claim 8, wherein an occurrence of deterioration is determined when the obtained exponent is smaller than the reference value.
